(19) United States
(12) Patent Application Publication
(10) Pub. No.: US 2024/0107679 A1
(43) Pub. Date: Mar. 28, 2024

(54) ASSEMBLY SHEET

(71) Applicant: NITTO DENKO CORPORATION, Osaka (JP)

(72) Inventors: Kenya TAKIMOTO, Osaka (JP); Hiroaki MACHITANI, Osaka (JP)

(73) Assignee: NITTO DENKO CORPORATION, Osaka (JP)

(21) Appl. No.: 18/466,533

(22) Filed: Sep. 13, 2023

(30) Foreign Application Priority Data
Sep. 22, 2022 (JP) 2022-151144

(51) Int. Cl. H05K 3/00

(52) U.S. Cl. CPC H05K 3/0052; H05K 2203/0169

(57) ABSTRACT

An assembly sheet includes a plurality of wiring circuit boards, a support portion, a connecting portion, and an opening portion. The wiring circuit board includes a first and a second wiring circuit board. The connecting portion includes a first and a second connecting portion connected to the first and the second wiring circuit board, respectively. The support portion and the connecting portion are not disposed between the first and the second wiring circuit board. The first wiring circuit board includes a first main body portion and a first protrusion portion. The second wiring circuit board includes a second main body portion. A first line passing a center of the first main body portion and a second line passing the center of the second main body portion are deviated so that a protrusion amount of the first protrusion portion with respect to the second main body portion is small.

### CROSS-REFERENCE TO RELATED APPLICATION

The present application claims priority from Japanese Patent Application No. 2022-151144 filed on Sep. 22, 2022, the contents of which are hereby incorporated by reference into this application.

### TECHNICAL FIELD

The present invention relates to an assembly sheet.

### BACKGROUND ART

Conventionally, an assembly sheet including a plurality of wiring circuit boards, a support frame, a joint portion, and a slit has been known (ref: for example, Patent Document 1 below).

In the assembly sheet described in Patent Document 1, the support frame supports the plurality of wiring circuit boards. The joint portion connects the plurality of wiring circuit boards to the support frame. The slit is disposed between the wiring circuit board and the support frame.

### CITATION LIST

### Patent Document

Patent Document 1: Japanese Unexamined Patent Publication No. 2006-210833

### SUMMARY OF THE INVENTION

### Problem to be Solved by the Invention

There is a demand to increase the number of wiring circuit boards in the one assembly sheet. Therefore, a configuration is proposed in which the support frame and the joint portion are not disposed between the wiring circuit boards which are adjacent to each other.

According to the above-described configuration, since a load applied to the support frame is increased, it is necessary to increase strength of the support frame.

On the other hand, the wiring circuit board may include a protrusion portion which protrudes toward the support frame in accordance with its application and purpose of the wiring circuit board. In such a case, since the support frame avoids the protrusion portion, there is a problem that the strength of the support frame is reduced.

The present invention provides an assembly sheet capable of suppressing a reduction in strength of the support portion, while increasing the number of wiring circuit boards in one assembly sheet.

### Means for Solving the Problem

The present invention [1] includes an assembly sheet including a plurality of wiring circuit boards, a support portion supporting the plurality of wiring circuit boards, a connecting portion connecting the plurality of wiring circuit boards to the support portion, and an opening portion disposed between the plurality of wiring circuit boards and the support portion, wherein the plurality of wiring circuit boards include a first wiring circuit board including a metal support layer, an insulating layer, and a conductive layer in order toward a thickness direction, and a second wiring circuit board including a metal support layer, an insulating layer, and a conductive layer in order toward the thickness direction and disposed spaced from the first wiring circuit board; the support portion includes a first support portion supporting the first wiring circuit board and the second wiring circuit board from one side in a first direction perpendicular to an alignment direction in which the first wiring circuit board and the second wiring circuit board are aligned and the thickness direction; the connecting portion includes a first connecting portion connecting the first wiring circuit board to the support portion and crossing the opening portion and a second connecting portion connecting the second wiring circuit board to the support portion and crossing the opening portion; the support portion is not disposed between the first wiring circuit board and the second wiring circuit board; the connecting portion is not disposed between the first wiring circuit board and the second wiring circuit board; the first wiring circuit board includes a first main body portion connected to the first connecting portion, and a first protrusion portion protruding from an end edge of the first main body portion toward the support portion; the second wiring circuit board includes a second main body portion connected to the second connecting portion and having the same shape as the first main body portion; and a first line passing a center of the first main body portion along the alignment direction and a second line passing the center of the second main body portion along the alignment direction are deviated so that a protrusion amount of the first protrusion portion with respect to one end edge of the second main body portion in the first direction is small.

In the assembly sheet, since the support portion is not disposed between the first wiring circuit board and the second wiring circuit board, and the connecting portion is not disposed between the first wiring circuit board and the second wiring circuit board. Therefore, it is possible to increase the number of wiring circuit boards in the one assembly sheet.

Further, since the first line and the second line are deviated so that the protrusion amount of the first protrusion portion is small, it is possible to suppress a reduction in strength of the support portion corresponding to the first protrusion portion.

The present invention [2] includes the assembly sheet described in [1], wherein one end edge of the second main body portion and one end edge of the first protrusion portion in the first direction coincide when projected in the alignment direction.

In the assembly sheet, since one end edge of the second main body portion and one end edge of the first protrusion portion coincide, it is possible to eliminate the protrusion amount of the first protrusion portion with respect to one end edge of the second main body portion. Therefore, it is not necessary to avoid the support portion corresponding to the first protrusion portion, and it is possible to further suppress the reduction in the strength of the support portion.

The present invention [3] includes the assembly sheet described in [1], wherein the support portion further includes a second support portion supporting the first wiring circuit board and the second wiring circuit board from the other side in the first direction; the second wiring circuit board further includes a second protrusion portion protruding from an end edge of the second main body portion toward the second support portion; and the first line and the second line are deviated so that a protrusion amount of the second protrusion portion with respect to the other end edge of the first main body portion in the first direction is small.

In the assembly sheet, since the first line and the second line are deviated so that the protrusion amount of the second protrusion portion with respect to the other end edge of the first main body portion is small, it is possible to suppress the reduction in the strength of the support portion corresponding to the second protrusion portion.

The present invention [4] includes the assembly sheet described in [3], wherein the other end edge of the first main body portion and the other end edge of the second protrusion portion in the first direction coincide when projected in the alignment direction.

In the assembly sheet, since the other end edge of the first main body portion and the other end edge of the second protrusion portion coincide, it is possible to eliminate the protrusion amount of the second protrusion portion with respect to the other end edge of the first main body portion. Therefore, it is not necessary to avoid the support portion corresponding to the second protrusion portion, and it is possible to further suppress the reduction in the strength of the support portion.

The present invention [5] includes the assembly sheet described in [1], wherein the first main body portion includes a first main portion and a first main body protrusion portion protruding from the first main portion toward the second wiring circuit board; the second main body portion includes a second main portion and a second main body protrusion portion protruding from the second main portion toward the first wiring circuit board; and the first main body protrusion portion and the second main body protrusion portion are adjacent to each other in the first direction.

In the assembly sheet, since the first main body protrusion portion protruding toward the second wiring circuit board and the second main body protrusion portion protruding toward the first wiring circuit board are adjacent to each other in the first direction, the first main body portion and the second main body portion are disposed compactly in the alignment direction. Therefore, it is possible to further increase the number of wiring circuit boards in the one assembly sheet.

The present invention [6] includes the assembly sheet described in any one of [1] to [5], wherein the support portion includes the metal support layer.

In the assembly sheet, since the support portion includes the metal support layer, it is possible to increase the strength of the support portion.

The present invention [7] includes the assembly sheet described in [5], wherein the support portion further includes a conductive layer.

In the assembly sheet, since the support portion further includes the conductive layer in addition to the metal support layer, it is possible to further increase the strength of the support portion.

The present invention [8] includes the assembly sheet described in [7], wherein the conductive layer includes a first layer and a second layer in order toward one side in the thickness direction.

The present invention [9] includes the assembly sheet described in [6], wherein the support portion further includes the insulating layer.

In the assembly sheet, since the support portion further includes the insulating layer in addition to the metal support layer, it is possible to increase toughness of the support portion. Therefore, it is possible to increase the strength of the support portion.

### Effect of the Invention

The assembly sheet of the present invention can suppress a reduction in strength of a support portion, while increasing the number of wiring circuit boards in one assembly sheet.

### BRIEF DESCRIPTION OF THE DRAWINGS

FIG. 1 shows a plan view of one embodiment of an assembly sheet of the present invention.

FIG. 2 shows an enlarged plan view of a substrate unit in the assembly sheet shown in FIG. 1.

FIG. 3 shows a cross-sectional view along an A-A line shown in FIG. 2.

FIGS. 4A to 4D show production process views of the assembly sheet shown in FIG. 3:

FIG. 4A illustrating a step (1) of forming a base insulating layer,

FIG. 4B illustrating a step (2) of forming a conductive layer,

FIG. 4C illustrating a step (3) of forming a cover insulating layer, and

FIG. 4D illustrating a step (4) of forming a resist.

### DESCRIPTION OF EMBODIMENTS

1. Assembly Sheet 1

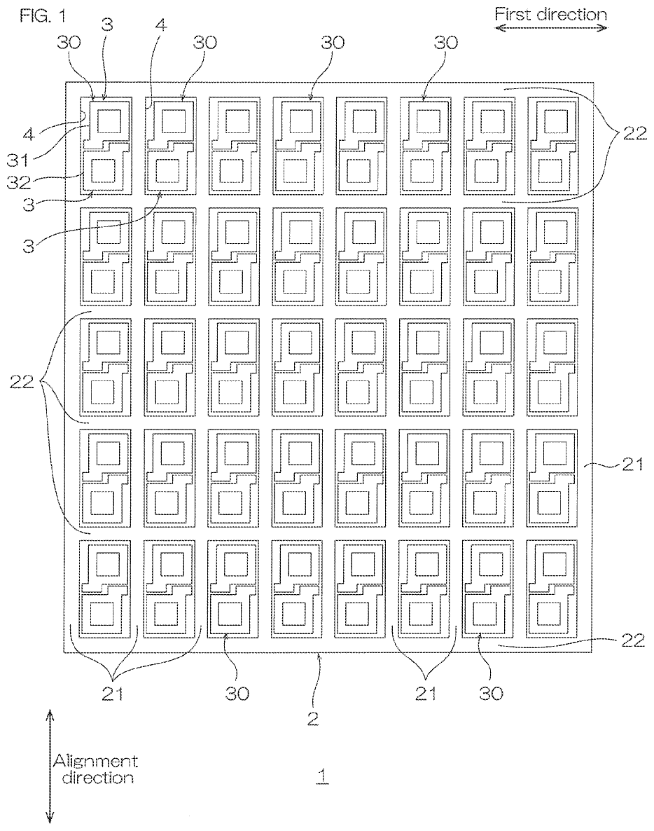

One embodiment of an assembly sheet of the present invention is described using FIGS. 1 to 3.

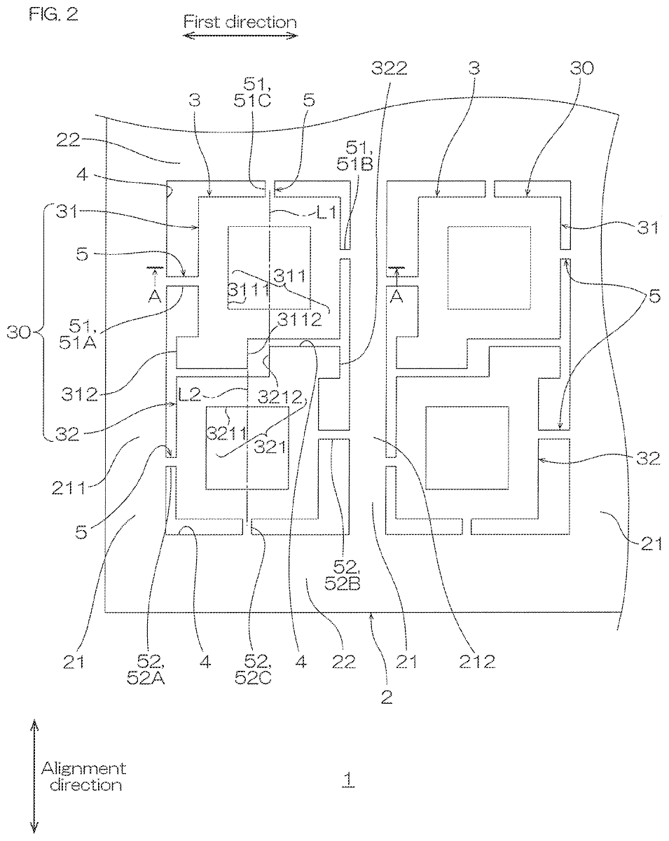

As shown in FIG. 1, an assembly sheet 1 includes a support portion 2, a plurality of wiring circuit boards 3, an opening portion 4, and a connecting portion 5 (ref: FIG. 2).

1.1 Support Portion 2

The support portion 2 forms an outer shape in the assembly sheet 1. In the present embodiment, the support portion 2 is disposed around the plurality of wiring circuit boards 3 to be described next. The support portion 2 supports the plurality of wiring circuit boards 3 to be described next. The support portion 2 includes a portion in parallel crosses, and a rectangular frame-shaped portion which is disposed at its end. Further, the support portion 2 includes a first portion 21 and a second portion 22.

The first portion 21 extends in an alignment direction (described later). In the present embodiment, the plurality of first portions 21 are disposed spaced from each other in a first direction (described later). As shown in FIG. 2, the first portion 21 includes a first support portion 211 and a second support portion 212. In other words, the support portion 2 includes the first support portion 211 and the second support portion 212. The first support portion 211 and the second support portion 212 are described later.

As shown in FIG. 1, the second portion 22 extends in the first direction. In the present embodiment, the plurality of second portions 22 are disposed spaced from each other in the alignment direction. Each of the plurality of second portions 22 connects the plurality of first portions 21.

1.2 Plurality of Wiring Circuit Boards 3

The plurality of wiring circuit boards 3 are supported by the above-described support portion 2. The plurality of wiring circuit boards 3 include a plurality of substrate units 30. The plurality of substrate units 30 are disposed spaced from each other in the alignment direction and the first direction. The plurality of substrate units 30 are separated by a portion of the second portion 22 in the alignment direction. Further, the plurality of substrate units 30 are separated by a portion of the first portion 21 in the first direction.

As shown in FIG. 2, the one substrate unit 30 includes a first wiring circuit board 31 and a second wiring circuit board 32. That is, the plurality of wiring circuit boards 3 include the first wiring circuit board 31 and the second wiring circuit board 32.

The first wiring circuit board 31 and the second wiring circuit board 32 are disposed spaced from each other. That is, the second wiring circuit board 32 is disposed spaced from the first wiring circuit board 31. The direction in which the first wiring circuit board 31 and the second wiring circuit board 32 are aligned is referred to as the “alignment direction”. The first wiring circuit board 31 and the second wiring circuit board 32 are disposed between the first support portion 211 and the second support portion 212 described above. That is, the first support portion 211, the first wiring circuit board 31, the second wiring circuit board 32, and the second support portion 212 are disposed in order in the first direction. The first direction is perpendicular to the alignment direction and a thickness direction. In the first direction, the second support portion 212 is located at the opposite side to the first support portion 211 with respect to the first wiring circuit board 31 and the second wiring circuit board 32.

1.2.1 Configuration of First Wiring Circuit Board 31

The first wiring circuit board 31 includes a first main body portion 311 and a first protrusion portion 312.

1.2.1.1 First Main Body Portion 311

In the present embodiment, the first main body portion 311 includes a generally rectangular frame shape. More specifically, the first main body portion 311 has a P-shape. The first main body portion 311 includes a first main portion 3111 and a first main body protrusion portion 3112.

The first main portion 3111 forms a generally rectangular frame shape. The first main portion 3111 is a main portion of the first main body portion 311.

The first main body protrusion portion 3112 protrudes from the other end edge of the first main portion 3111 in the alignment direction toward the second wiring circuit board 32. In the present embodiment, the first main body protrusion portion 3112 protrudes from one end portion of the first main portion 3111 in the first direction. In the present embodiment, the first main body protrusion portion 3112 has a generally rectangular shape.

1.2.1.2 First Protrusion Portion 312

The first protrusion portion 312 protrudes from one end edge of the first main body protrusion portion 3112 in the first direction toward the first support portion 211. That is, the first protrusion portion 312 protrudes from an end edge of the first main body portion 311 toward the support portion 2.

1.2.3 Configuration of Second Wiring Circuit Board 32

The second wiring circuit board 32 includes a second main body portion 321 and a second protrusion portion 322.

1.2.3.1 Second Main Body Portion 321

The second main body portion 321 has the same shape as the first main body portion 311. Specifically, the shape of the second main body portion 321 is the same as the shape obtained by rotating the first main body portion 311 at 180 degrees in a plane direction (the alignment direction and the first direction).

More specifically, the second main body portion 321 has a P-shape. The second main body portion 321 includes a second main portion 3211 and a second main body protrusion portion 3212.

The second main portion 3211 has the same shape as the first main portion 3111. The second main portion 3211 is a main portion of the second main body portion 321.

The second main body protrusion portion 3212 has the same shape as the first main body protrusion portion 3112. Specifically, the second main body protrusion portion 3212 protrudes from one end edge of the second main portion 3211 in the alignment direction toward the first wiring circuit board 31. In the present embodiment, the second main body protrusion portion 3212 protrudes from the other end portion of the second main portion 3211 in the first direction.

The first main body protrusion portion 3112 and the second main body protrusion portion 3212 are adjacent to each other in the first direction. On the other hand, the first main body protrusion portion 3112 is not adjacent to the second main portion 3211. The second main body protrusion portion 3212 is not adjacent to the first main portion 3111.

Then, a first line L1 and a second line L2 are deviated so that a protrusion amount of the first protrusion portion 312 with respect to one end edge of the second main portion 3211 in the first direction is small. That is, the first line L1 and the second line L2 are deviated so that the protrusion amount of the first protrusion portion 312 with respect to one end edge of the second main body portion 321 is small.

The first line L1 passes a center of the first main portion 3111 of the first main body portion 311 along the alignment direction.

The second line L2 passes the center of the second main portion 3211 of the second main body portion 321 along the alignment direction.

In the present embodiment, the second line L2 is deviated on one side (the first support portion 211) with respect to the first line L1 in the first direction.

A gap (deviation amount) between the first line L1 and the second line L2 in the first direction is, for example, 0.1 mm or more, preferably 0.5 mm or more, and for example, 2 mm or less, preferably 1.5 mm or less. When the gap (deviation amount) between the first line L1 and the second line L2 in the first direction is the above-described upper limit or less, it is possible to increase the taken number of the substrate unit 30 in the first direction.

Further, in the present embodiment, preferably, when projected in the alignment direction, one end edge of the second main portion 3211 and one end edge of the first protrusion portion 312 in the first direction coincide. That is, when projected in the alignment direction, one end edge of the second main body portion 321 and one end edge of the first protrusion portion 312 in the first direction coincide. In this case, the protrusion amount of the first protrusion portion 312 with respect to one end edge of the second main portion 3211 in the first direction is none (zero). The above-described “coincide” includes both a case of completely coinciding and a case where the two one end edges are within a tolerance range of 10 μm or more and 100 μm or less (case of being deviated) in accordance with designs of the first wiring circuit board 31 and the second wiring circuit board 32.

1.2.3.2 Second Protrusion Portion 322

The second protrusion portion 322 protrudes from the other end edge of the second main body protrusion portion 3212 in the first direction toward the second support portion 212. That is, the second protrusion portion 322 protrudes from the end edge of the second main body portion 321 toward the support portion 2.

The first line L1 and the second line L2 are deviated so that the protrusion amount of the second protrusion portion 322 with respect to the other end edge of the first main portion 3111 in the first direction is small.

Further, in the present embodiment, preferably, when projected in the alignment direction, the other end edge of the first main portion 3111 and the other end edge of the second protrusion portion 322 in the first direction coincide. That is, when projected in the alignment direction, the other end edge of the first main body portion 311 and the other end edge of the second protrusion portion 322 in the first direction coincide. In this case, the protrusion amount of the second protrusion portion 322 with respect to the other end edge of the first main portion 3111 in the first direction is none (zero). The above-described “coincide” includes both a case of completely coinciding and a case where the two other end edges are within a tolerance range of 10 μm or more and 100 μm or less (case of being deviated) in accordance with the designs of the first wiring circuit board 31 and the second wiring circuit board 32.

1.3 First Support Portion 211, Second Support Portion 212

The first support portion 211 supports the first wiring circuit board 31 and the second wiring circuit board 32 from one side in the first direction. In the present embodiment, the first support portion 211 has a linear shape extending in the alignment direction. Preferably, the other end edge of the first support portion 211 in the first direction has a linear shape. The other end edge of the first support portion 211 goes toward the first protrusion portion 312.

The second support portion 212 supports the first wiring circuit board 31 and the second wiring circuit board 32 from the other side in the first direction. In the present embodiment, the second support portion 212 has a linear shape extending in the alignment direction. Preferably, one end edge of the second support portion 212 in the first direction has a linear shape. One end edge of the second support portion 212 goes toward the second protrusion portion 322.

1.3 Opening Portion 4

The opening portion 4 is disposed between the plurality of wiring circuit boards 3 and the support portion 2. In the present embodiment, the opening portion 4 is a slit passing through the assembly sheet 1 in the thickness direction. The opening portion 4 defines the outer shape of the plurality of wiring circuit boards 3.

Between the first support portion 211, and the first wiring circuit board 31 and the second wiring circuit board 32, a length in the first direction of the opening portion 4 corresponding to the first protrusion portion 312 and the second main portion 3211 is shorter than the length in the first direction of the opening portion 4 corresponding to the first main portion 3111.

Between the second support portion 212, and the first wiring circuit board 31 and the second wiring circuit board 32, the length in the first direction of the opening portion 4 corresponding to the second protrusion portion 322 and the first main portion 3111 is shorter than the length in the first direction of the opening portion 4 corresponding to the second main portion 3211.

Between the first wiring circuit board 31 and the second wiring circuit board 32, the opening portion 4 has a crank shape corresponding to the first main body protrusion portion 3112 and the second main body protrusion portion 3212.

1.4 Connecting Portion 5

The connecting portion 5 connects the plurality of wiring circuit boards 3 to the support portion 2. Specifically, the connecting portion 5 connects each of the plurality of wiring circuit boards 3 to the support portion 2. The connecting portion 5 includes a first connecting portion 51 and a second connecting portion 52.

1.4.1 First Connecting Portion 51

The first connecting portion 51 connects the first wiring circuit board 31 to the support portion 2. Specifically, the first connecting portion 51 connects the first main body portion 311 to the support portion 2. Therefore, the first wiring circuit board 31 is supported by the support portion 2 via the first connecting portion 51. The first connecting portion 51 crosses the opening portion 4. In other words, the first connecting portion 51 bridges the first wiring circuit board 31 and the support portion 2. The plurality of first connecting portions 51 are disposed spaced from each other along the periphery of the first wiring circuit board 31. Specifically, the first connecting portion 51 includes first connecting portions 51A, 51B, and 51C. The first connecting portion 51A connects the first support portion 211 to the first main portion 3111. The first connecting portion 51B connects the second support portion 212 to the first main portion 3111. The first connecting portion 51C connects the second portion 22 of the support portion 2 to the first main portion 3111.

1.4.2 Second Connecting Portion 52

The second connecting portion 52 connects the second wiring circuit board 32 to the support portion 2. Specifically, the second connecting portion 52 connects the second main body portion 321 to the support portion 2. Therefore, the second wiring circuit board 32 is supported by the support portion 2 via the second connecting portion 52. The second connecting portion 52 crosses the opening portion 4. In other words, the second connecting portion 52 bridges the second wiring circuit board 32 and the support portion 2. The plurality of second connecting portions 52 are disposed spaced from each other along the periphery of the second wiring circuit board 32. Specifically, the second connecting portion 52 includes second connecting portions 52A, 52B, and 52C. The second connecting portion 52A connects the first support portion 211 to the second main portion 3211. The second connecting portion 52B connects the second support portion 212 to the second main portion 3211. The second connecting portion 52C connects the second portion 22 of the support portion 2 to the second main portion 3211.

On the other hand, the connecting portion 5 is not disposed between the first wiring circuit board 31 and the second wiring circuit board 32. Further, the support portion 2 is also not disposed between the first wiring circuit board 31 and the second wiring circuit board 32. That is, both the connecting portion 5 and the support portion 2 are not disposed between the first wiring circuit board 31 and the second wiring circuit board 32. Preferably, there is only the opening portion 4 in the first wiring circuit board 31 and the second wiring circuit board 32.

1.5 Layer Configuration of Assembly Sheet 1

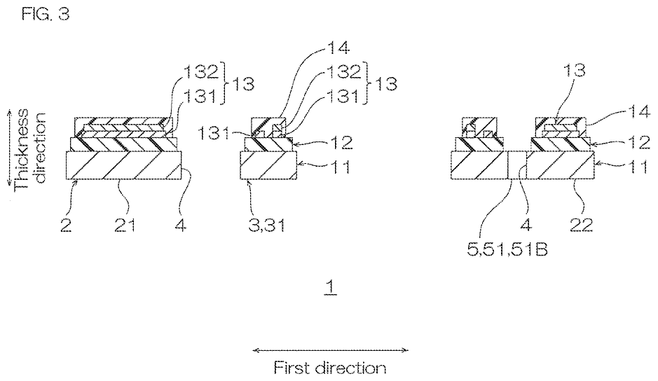

As shown in FIG. 3, the assembly sheet 1 includes the metal support layer 11, the base insulating layer 12 as one example of the insulating layer, the conductive layer 13, and the cover insulating layer 14 as one example of the insulating layer. Further, each of the first wiring circuit board 31 and the second wiring circuit board 32 (not shown in FIG. 3) includes the metal support layer 11, the base insulating layer 12, and the conductive layer 13 in order toward the thickness direction.

1.5.1 Metal Support Layer 11

The metal support layer 11 is located in the other end portion of the assembly sheet 1 in the thickness direction. The metal support layer 11 forms the outer shape of the assembly sheet 1. Each of the metal support layers 11 is included in the support portion 2, the plurality of wiring circuit boards 3, and the connecting portion 5. Further, the metal support layer 11 has the opening portion 4. A material for the metal support layer 11 is, for example, a rigid material. Examples of the rigid material include stainless steel, 42-alloy, aluminum, copper-beryllium, phosphor bronze, copper, silver, nickel, chromium, titanium, tantalum, platinum, gold, and copper alloys. As the rigid material, from the viewpoint of ensuring strength of the support portion 2, preferably, stainless steel and a copper alloy are used. A thickness of the metal support layer 11 is, for example, 15 μm or more, preferably 100 μm or more, and for example, 500 μm or less, preferably 250 μm or less.

1.5.2 Base Insulating Layer 12

The base insulating layer 12 is disposed on one surface of the metal support layer 11 in the thickness direction. The base insulating layer 12 is in contact with one surface of the metal support layer 11 in the thickness direction. Each of the base insulating layers 12 is included in, for example, the support portion 2, the plurality of wiring circuit boards 3, and the connecting portion 5, and is preferably included in the support portion 2 and the plurality of wiring circuit boards 3. Further, the base insulating layer 12 has the opening portion 4. Examples of the material for the base insulating layer 12 include resins, and preferably, polyimide is used. The thickness of the base insulating layer 12 is, for example, 1 μm or more, preferably 5 μm or more, and for example, 25 μm or less, preferably, 15 μm or less.

1.5.3 Conductive Layer 13

The conductive layer 13 is disposed on one surface of the base insulating layer 12 in the thickness direction. The conductive layer 13 is in contact with one surface of the base insulating layer 12 in the thickness direction. Each of the conductive layers 13 is included in the support portion 2 and the plurality of wiring circuit boards 3. The conductive layer 13 is a single layer or a plurality of layers.

A portion of the conductive layer 13 includes a first layer 131 and a second layer 132 in order toward one side in the thickness direction. The first layer 131 is in contact with one surface of the base insulating layer 12. The second layer 132 corresponds to a portion of the first layer 131. The second layer 132 is disposed on one surface of the first layer 131 in the thickness direction. In the present embodiment, the first layer 131 is a first reinforcement layer in the support portion 2. The second layer 132 may be a raised layer in the wiring circuit board 3, and also a reinforcement layer in the support portion 2. A remaining portion of the conductive layer 13 is the above-described first layer 131. When the thicknesses of the first layer 131 and that of the second layer 132 are different from each other, the second layer 132 may be a signal wiring which is disposed on one surface of the base insulating layer 12 instead of the raised layer.

Examples of the material for the conductive layer 13 include conductors. As the conductor, preferably, copper is used. The materials for the first layer 131 and the second layer 132 are the same or different from each other.

The thickness of the conductive layer 13 is, for example, 3 μm or more, preferably 10 μm or more, and for example, 60 μm or less, preferably 40 μm or less. The thickness of each of the first layer 131 and the second layer 132 is, for example, 1 μm or more, preferably 3 μm or more, and for example, 50 μm or less, preferably 30 μm or less.

1.5.4 Cover Insulating Layer 14

The cover insulating layer 14 is disposed on one surface of the base insulating layer 12 in the thickness direction. The cover insulating layer 14 covers one surface of the conductive layer 13 in the thickness direction and the peripheral side surfaces of the conductive layer 13. Each of the cover insulating layers 14 is included in, for example, the support portion 2, the plurality of wiring circuit boards 3, and the connecting portion 5, and is preferably included in the support portion 2 and the plurality of wiring circuit boards 3. Although not shown, the cover insulating layer 14 may be also included in the connecting portion 5. Further, the cover insulating layer 14 has the opening portion 4.

Examples of the material for the cover insulating layer 14 include flexible materials. Examples of the flexible material include resins, and preferably, polyimide is used. The thickness of the cover insulating layer 14 is, for example, 1 μm or more, preferably 5 μm or more, and for example, 25 μm or less, preferably 15 μm or less.

1.6 Method for Producing Assembly Sheet 1

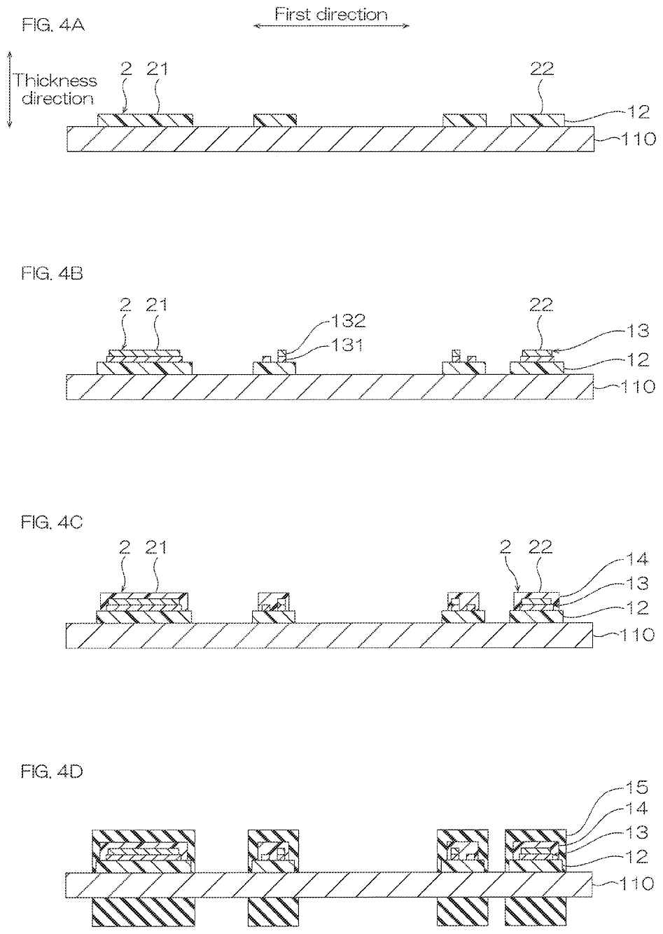

A method for producing the assembly sheet 1 is described using FIGS. 4A to 4D and FIG. 3. The method for producing the assembly sheet 1 includes steps (1) to (4). The steps (1) to (4) are carried out in order.

1.6.1 Step (1)

As shown in FIG. 4A, in the step (1), the base insulating layer 12 is formed. Specifically, the base insulating layer 12 is formed on one surface of a metal support board 110 in the thickness direction.

The metal support board 110 is a metal board for forming the metal support layer 11. The metal support board 110 is made of the same material as the metal support layer 11, and has the same thickness as the metal support layer 11.

For example, the resin is coated onto one surface of the metal support board 110, thereby forming the base insulating layer 12 having a pattern corresponding to each of the support portion 2 and the plurality of wiring circuit boards 3 (ref: FIG. 3) by photolithography.

1.6.2 Step (2)

As shown in FIG. 4B, in the step (2), the conductive layer 13 is formed. Specifically, the conductive layer 13 is formed on one surface of the base insulating layer 12 in the thickness direction. For example, the conductive layer 13 is formed by a conductive pattern forming method. Examples of the conductive pattern forming method include additive methods and subtractive methods, and preferably, an additive method is used. The conductive layer 13 having a pattern included in each of the support portion 2 and the plurality of wiring circuit boards 3 is formed by the conductive pattern forming method. In the case of forming the first layer 131 and the second layer 132, the above-described conductive pattern forming method is carried out a plurality of times (twice).

1.6.3 Step (3)

As shown in FIG. 4C, in the step (3), the cover insulating layer 14 is formed. Specifically, the cover insulating layer 14 is formed on one surface of the base insulating layer 12 in the thickness direction. For example, a resin is coated onto one surfaces of the base insulating layer 12 and the conductive layer 13, thereby forming the cover insulating layer 14 having a pattern corresponding to each of the support portion 2 and the plurality of wiring circuit boards 3 by the photolithography.

1.6.4 Step (4)

As shown in FIG. 3, in the step (4), the metal support layer 11 is formed. Specifically, the outer shape of the metal support board 110 is processed. Examples of the outer shape processing include etching, punching, and laser. As the outer shape processing, preferably, from the viewpoint of productivity, etching is used.

To process the outer shape of the metal support board 110 using the etching, first, as shown in FIG. 4D, a resist 15 is disposed on each of one surface and the other surface of the metal support board 110 in the thickness direction. The resist 15 has a reverse pattern of the metal support layer 11 (ref: FIG. 3) (reversed pattern). For example, the resist 15 is prepared from a dry film resist.

Thereafter, the metal support board 110 exposed from the resist 15 is removed using the etching. Thereafter, the resist 15 is removed.

As shown in FIG. 3, the assembly sheet 1 is thus produced.

Thereafter, though not shown, the plurality of wiring circuit boards 3 are taken out from the assembly sheet 1. Specifically, by cutting the connecting portion 5, the plurality of wiring circuit boards 3 are cut from the support portion 2.

2. Function and Effect of One Embodiment

As shown in FIG. 2, in the assembly sheet 1, the support portion 2 is not disposed between the first wiring circuit board 31 and the second wiring circuit board 32, and the connecting portion 5 is not disposed between the first wiring circuit board 31 and the second wiring circuit board 32. Therefore, it is possible to increase the number (taken number) of wiring circuit boards 3 in the one assembly sheet 1.

Further, since the first line L1 and the second line L2 are deviated, and the protrusion amount of the first protrusion portion 312 is small, it is not necessary to avoid the support portion 2 (the first support portion 211) corresponding to the first protrusion portion 312, and it is possible to suppress a reduction in the strength of the support portion 2 (the first support portion 211).

In the assembly sheet 1, since one end edge of the second main portion 3211 of the second main body portion 321, and one end edge of the first protrusion portion 312 coincide, it is possible to eliminate the protrusion amount of the first protrusion portion 312 with respect to one end edge of the second main portion 3211. Therefore, it is possible to further suppress the reduction in the strength of the support portion 2 (the first support portion 211) corresponding to the first protrusion portion 312.

Further, since the first line L1 and the second line L2 are deviated, in the assembly sheet 1, the protrusion amount of the second protrusion portion 322 with respect to the other end edge of the first main portion 3111 of the first main body portion 311 is small. Therefore, it is not necessary to avoid the support portion 2 (the second support portion 212) corresponding to the second protrusion portion 322, and it is possible to further suppress the reduction in the strength of the support portion (the second support portion 212).

In the assembly sheet 1, since the other end edge of the first main portion 3111 of the first main body portion 311, and the other end edge of the second protrusion portion 322 coincide, it is possible to eliminate the protrusion amount of the second protrusion portion 322 with respect to the other end edge of the first main portion 3111. Therefore, it is possible to further suppress the reduction in the strength of the support portion 2 (the second support portion 212) corresponding to the second protrusion portion 322.

In the assembly sheet 1, the first main body protrusion portion 3112 protruding toward the second wiring circuit board 32, and the second main body protrusion portion 3212 protruding toward the first wiring circuit board 31 are adjacent to each other in the first direction. Therefore, the first main body portion 311 and the second main body portion 321 are disposed compactly in the alignment direction. Therefore, it is possible to further increase the number (taken number) of wiring circuit boards 3 in the one assembly sheet 1.

As shown in FIG. 3, in the assembly sheet 1, since the support portion 2 includes the metal support layer 11, it is possible to increase the strength of the support portion 2.

In the assembly sheet 1, since the support portion 2 further includes the conductive layer 13 in addition to the metal support layer 11, it is possible to further increase the strength of the support portion 2.

In the assembly sheet 1, since the support portion 2 further includes the base insulating layer 12 and the cover insulating layer 14 in addition to the metal support layer 11, it is possible to increase toughness of the support portion 2. Therefore, it is possible to increase the strength of the support portion 2.

### 3. Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

### 3.1 First Modified Example

Although not shown, the first protrusion portion 312 may also protrude from the first main portion 3111 of the first main body portion 311 toward the support portion 2 (the first support portion 211) instead of from the first main body protrusion portion 3112 of the first main body portion 311.

### 3.2 Second Modified Example

Although not shown, the second protrusion portion 322 may also protrude from the second main portion 3211 of the second main body portion 321 toward the support portion 2 (the second support portion 212) instead of from the second main body protrusion portion 3212 of the second main body portion 321.

### 3.3 Third Modified Example

The support portion 2 may also include, as the insulating layer, any one of the base insulating layer 12 and the cover insulating layer 14, and may not include the other.

### 3.4 Fourth Modified Example

The support portion 2 may also not include both the base insulating layer 12 and the cover insulating layer 14.

### 3.5 Fifth Modified Example

The support portion 2 may also not include the conductive layer 13.

Of one embodiment, and the third modified example to the fifth modified example, preferably, one embodiment is used. In one embodiment, since the support portion 2 includes the metal support layer 11, the base insulating layer 12, the conductive layer 13, and the cover insulating layer 14, it is possible to increase the strength of the support portion 2.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF REFERENCE NUMERALS

1 Assembly sheet
2 Support portion
3 Wiring circuit board
4 Opening portion
5 Connecting portion
11 Metal support layer
12 Base insulating layer
13 Conductive layer
14 Cover insulating layer
31 First wiring circuit board
32 Second wiring circuit board
51 First connecting portion
52 Second connecting portion
131 First layer
132 Second layer
211 First support portion
212 Second support portion
311 First main body portion
312 First protrusion portion
321 Second main body portion
322 Second protrusion portion
3111 First main portion
3112 First main body protrusion portion
3211 Second main portion
3212 Second main body protrusion portion
L1 First line
L2 Second line

1. An assembly sheet comprising:
a plurality of wiring circuit boards,
a support portion supporting the plurality of wiring circuit boards,
a connecting portion connecting the plurality of wiring circuit boards to the support portion, and
an opening portion disposed between the plurality of wiring circuit boards and the support portion, wherein
the plurality of wiring circuit boards include
a first wiring circuit board including a metal support layer, a base insulating layer, and a conductive layer in order toward a thickness direction, and
a second wiring circuit board including a metal support layer, a base insulating layer, and a conductive layer in order toward the thickness direction and disposed spaced from the first wiring circuit board;
the support portion includes a first support portion supporting the first wiring circuit board and the second wiring circuit board from one side in a first direction perpendicular to an alignment direction in which the first wiring circuit board and the second wiring circuit board are aligned and the thickness direction;
the connecting portion includes
a first connecting portion connecting the first wiring circuit board to the support portion and crossing the opening portion and
a second connecting portion connecting the second wiring circuit board to the support portion and crossing the opening portion;
the support portion is not disposed between the first wiring circuit board and the second wiring circuit board;
the connecting portion is not disposed between the first wiring circuit board and the second wiring circuit board;
the first wiring circuit board includes
a first main body portion connected to the first connecting portion, and
a first protrusion portion protruding from an end edge of the first main body portion toward the support portion;
the second wiring circuit board includes
a second main body portion connected to the second connecting portion and having the same shape as the first main body portion; and
a first line passing a center of the first main body portion along the alignment direction and a second line passing the center of the second main body portion along the alignment direction are deviated so that a protrusion amount of the first protrusion portion with respect to one end edge of the second main body portion in the first direction is small.

2. The assembly sheet according to claim 1, wherein
one end edge of the second main body portion and one end edge of the first protrusion portion in the first direction coincide when projected in the alignment direction.

3. The assembly sheet according to claim 1, wherein
the support portion further includes a second support portion supporting the first wiring circuit board and the second wiring circuit board from the other side in the first direction;
the second wiring circuit board further includes a second protrusion portion protruding from an end edge of the second main body portion toward the second support portion; and
the first line and the second line are deviated so that a protrusion amount of the second protrusion portion with respect to the other end edge of the first main body portion in the first direction is small.

4. The assembly sheet according to claim 3, wherein
the other end edge of the first main body portion and the other end edge of the second protrusion portion in the first direction coincide when projected in the alignment direction.

5. The assembly sheet according to claim 1, wherein
the first main body portion includes a first main portion and a first main body protrusion portion protruding from the first main portion toward the second wiring circuit board;
the second main body portion includes a second main portion and a second main body protrusion portion protruding from the second main portion toward the first wiring circuit board; and
the first main body protrusion portion and the second main body protrusion portion are adjacent to each other in the first direction.

6. The assembly sheet according to claim 1, wherein
the support portion includes the metal support layer.

7. The assembly sheet according to claim 5, wherein
the support portion further includes a conductive layer.

8. The assembly sheet according to claim 7, wherein
the conductive layer includes a first layer and a second layer in order toward one side in the thickness direction.

9. The assembly sheet according to claim 6, wherein
the support portion further includes the insulating layer.
